(19) United States
(12) Patent Application Publication
(10) Pub. No.: US 2024/0389220 A1
(43) Pub. Date: Nov. 21, 2024

(54) REDUCED BALL GRID ARRAY PAD CAPACITANCE

(71) Applicant: DELL PRODUCTS L.P., Round Rock, TX (US)

(72) Inventors: Sandor Farkas, Round Rock, TX (US); Bhyrav Mutnury, Austin, TX (US)

(21) Appl. No.: 18/318,878

(22) Filed: May 17, 2023

(51) Int. Cl. H05K 1/02; H05K 1/11

(52) U.S. Cl. CPC H05K 1/0225; H05K 1/112; H05K 1/181; H05K 2201/0723; H05K 2201/09509; H05K 2201/10734

(57) ABSTRACT

A PCB includes a first BGA pad on a first surface of the PCB, a second BGA pad on the first surface, a metal layer within the PCB that includes a shield pad with a first portion directly below the first BGA pad and a second portion coupled to the first portion and directly below the second BGA pad, and a plated via that couples the second BGA pad to the shield pad. The first BGA pad is collocated with a first BGA ball of a BGA device and is associated with a first signal of the BGA device. The second BGA pad is collocated with a second BGA ball of the BGA device and is associated with a second signal of the BGA device. The first signal and the second signal are a common signal.

### FIELD OF THE DISCLOSURE

This disclosure generally relates to information handling systems, and more particularly relates to providing reduced ball grid array (BGA) pad capacitance.

### BACKGROUND

As the value and use of information continues to increase, individuals and businesses seek additional ways to process and store information. One option is an information handling system. An information handling system generally processes, compiles, stores, and/or communicates information or data for business, personal, or other purposes. Because technology and information handling needs and requirements may vary between different applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, reservations, enterprise data storage, or global communications. In addition, information handling systems may include a variety of hardware and software resources that may be configured to process, store, and communicate information and may include one or more computer systems, data storage systems, and networking systems.

### SUMMARY

A PCB may include a first BGA pad on a first surface of the PCB, a second BGA pad on the first surface, a metal layer within the PCB that includes a shield pad with a first portion directly below the first BGA pad and a second portion coupled to the first portion and directly below the second BGA pad, and a plated via that couples the second BGA pad to the shield pad. The first BGA pad may be collocated with a first BGA ball of a BGA device and is associated with a first signal of the BGA device. The second BGA pad may be collocated with a second

BGA ball of the BGA device and is associated with a second signal of the BGA device. The first signal and the second signal may be a common signal.

### BRIEF DESCRIPTION OF THE DRAWINGS

It will be appreciated that for simplicity and clarity of illustration, elements illustrated in the Figures have not necessarily been drawn to scale. For example, the dimensions of some of the elements are exaggerated relative to other elements. Embodiments incorporating teachings of the present disclosure are shown and described with respect to the drawings presented herein, in which:

FIG. 1A is a diagram illustrating a side view of an information handling system as may be known in the prior art;

FIG. 1B is a circuit model of the information handling systems of FIG. 1A;

FIG. 2A is a diagram illustrating a side view of another information handling system as may be known in the prior art;

FIG. 2B is a circuit model of the information handling systems of FIG. 2A;

FIG. 3A is a diagram illustrating a side view of an information handling system according to an embodiment of the current disclosure;

FIG. 3B is a circuit model of the information handling systems of FIG. 3A;

FIG. 4A is a top perspective view of a printed circuit board (PCB) according to an embodiment of the current disclosure;

FIG. 4B is a bottom perspective view of the PCB of FIG. 4A; and

FIG. 5 is a block diagram illustrating a generalized information handling system according to another embodiment of the present disclosure;

The use of the same reference symbols in different drawings indicates similar or identical items.

### DETAILED DESCRIPTION OF DRAWINGS

The following description in combination with the Figures is provided to assist in understanding the teachings disclosed herein. The following discussion will focus on specific implementations and embodiments of the teachings. This focus is provided to assist in describing the teachings, and should not be interpreted as a limitation on the scope or applicability of the teachings. However, other teachings can certainly be used in this application. The teachings can also be used in other applications, and with several different types of architectures, such as distributed computing architectures, client/server architectures, or middleware server architectures and associated resources.

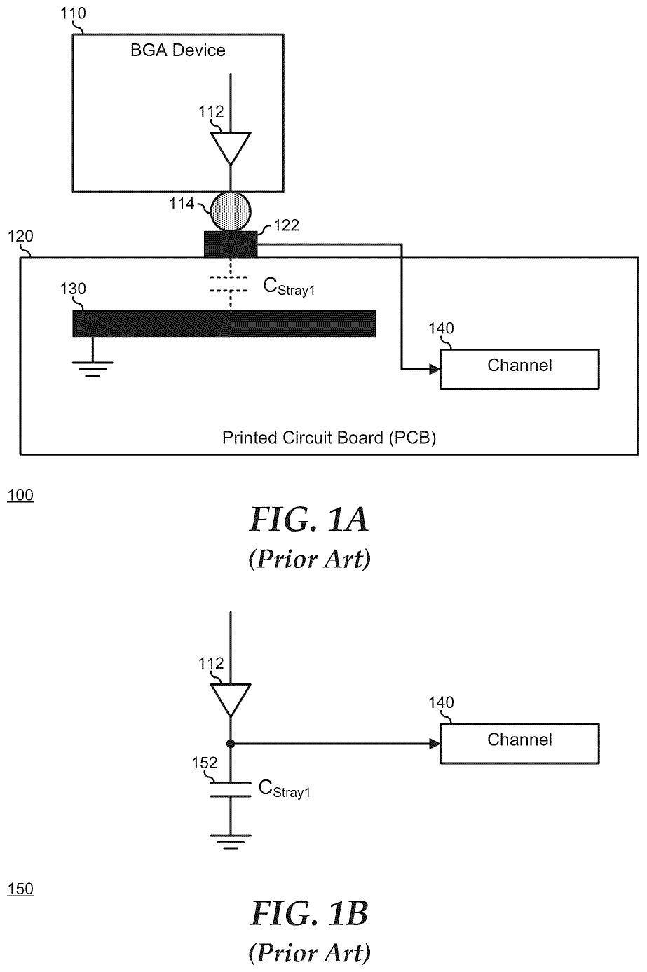

FIG. 1A illustrates an information handling system 100 as may be known in the art. Information handling system 100 includes an integrated circuit device 110 packaged in a ball-grid array (BGA) type package form factor (referred to hereinafter as “BGA device 110”), that is affixed to a printed circuit board (PCB) 120. BGA device 110 includes a signal interface 112 that is available as an exterior input or output via a BGA ball 114. While shown as an output buffer, signal interface 112 may be understood to represent any type of signal driver, signal receiver, signal transceiver, or other type of signal interface as needed or desired. Signal interface 112 typically represents a signal associated with a high speed data link that conducts data transactions with another device (not illustrated). For example, signal interface 112 may represent a transmit or receive circuit for a high speed serial data interface such as a Peripheral Component Interface-Express (PCIe) interface, a Serial ATA (SATA) interface, or the like, a transceiver circuit for a high speed bi-directional data interface such as a double data rate (DDR) interface, or the like. Further, signal interface 112 may represent a single-ended signal interface, a first signal interface of a differential pair signal interface, or another type of signal interface, as needed or desired.

PCB 120 includes a BGA pad 122, a ground plane 130, and a signal channel 140. Signal interface 112 is electrically connected to BGA ball 114, and BGA device 110 is affixed to PCB 120 such that BGA ball 114 is electrically connected to BGA pad 122. Typically, BGA device 110 is both mechanically affixed to PCB 120, and electrically connected to various circuit traces on the PCB by a soldering process. The details of assembly of PCBs and particularly of mechanically affixing and electrically connecting BGA devices to PCBs, are known in the art and will not be further described herein, except as may be needed to illustrate the current embodiments.

BGA pad 122 is shown as being on a top surface of PCB and being connected to channel 140. Channel 140 will be understood to carry the signal provided by signal interface 112 to the other device with which the signal interface conducts data transactions. Channel 140 is illustrated as being provided within PCB 120. However, channel 140 may be implemented as a microstrip trace provided on a surface of the associated PCB, as a strip line trace provided on one or more internal metal layer of the PCB and including one or more metallized circuit vias that conduct the associated signal between the surface layers and the internal metal layers, or as a combination of microstrip traces and strip line traces, as needed or desired. The details of high speed data channel trace routing are known in the art and will not be further described herein, except as may be needed to illustrate the current embodiments.

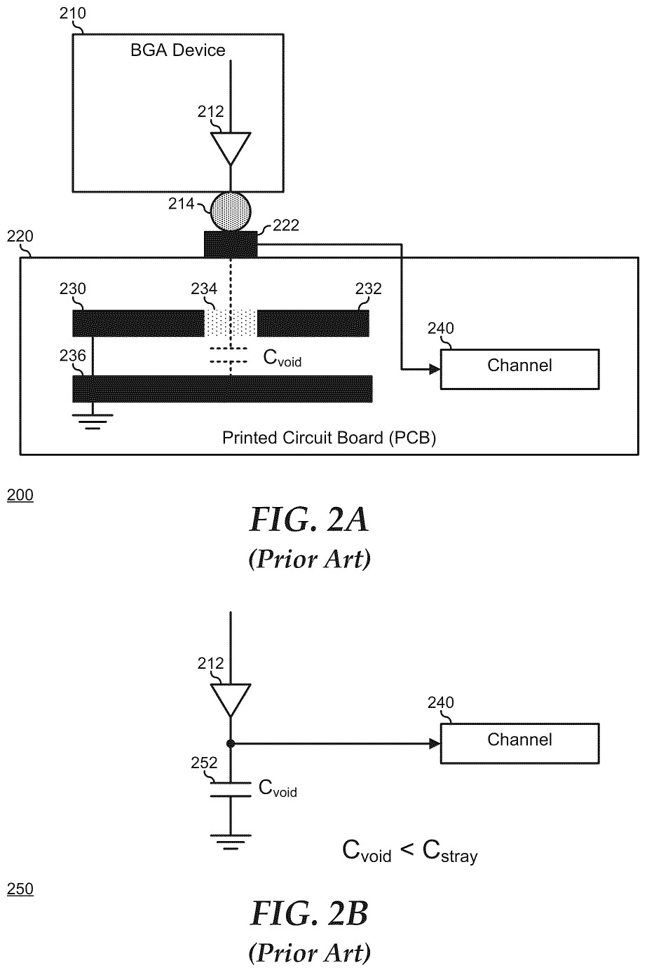

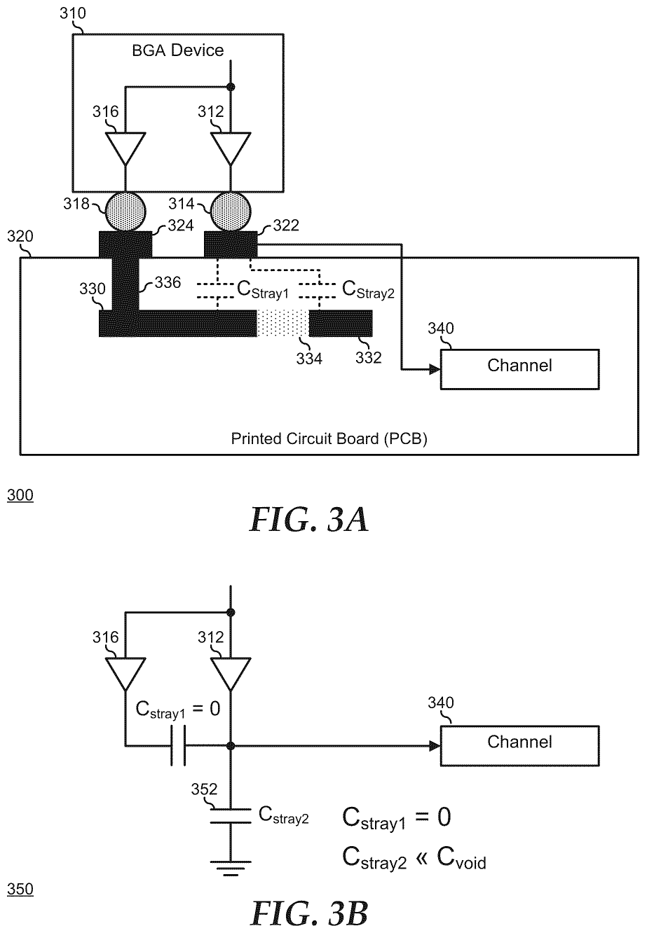

Ground plane 130 represents an internal metal layer of PCB 120 that is electrically connected to a system ground of information handling system 100, and may typically be understood to represent a grounded metal layer closest to the surface of the PCB proximate to BGA pad 122. Ground plane 130 may be provided as a circuit ground layer for the components and circuits of information handling system 100, or as a reference plane for shielding high speed circuit traces such as channel 140, as needed or desired. The dimensions provided herein, particularly with reference to FIG. 1A, and FIGS. 2A and 3A below, are illustrative and are not meant to represent actual dimensions for an information handling system. For example the size and shape of BGA ball 114, the thicknesses of BGA pad 122 and of ground plane 130, and the spacing between the BGA pad and the ground plane are provided for illustrative purposes only.

FIG. 1B illustrates a circuit model of information handling system 100, where signal interface 112 is connected to channel 140, and to the ground plane of the information handling system through an effective capacitor 152. Capacitor 152 represents a stray capacitance between the metallization of BGA pad 122 and the metallization of ground plane 130. The capacitance of capacitor 152 (Cstray₁) will be understood to be typically in a range of 100-200 pico-Farads (pF). At a time when a PCB topology similar to PCB 120 was common, the signal frequency of signal interface 112 was considerably lower than the signal frequency of modern high-speed data interfaces, and, were the topology of PCB 120 be provided for modern high-speed data interfaces, the stray capacitance 142 would typically result in an impedance reduction of 20-30 ohms (Ω), and such a topology would be even more highly unsuitable for the frequency ranges of soon upcoming high-speed data interfaces (for example 8-10 giga-transfers per second (GTs) or more).

FIG. 2A illustrates an information handling system 200 as may be known in the art. Information handling system 200 is similar to information handling systems 100, and includes a BGA device 210 that is affixed to a PCB 220. BGA device 210 includes a signal interface 212 that is similar to signal interface 112, and that is available as an exterior input or output via a BGA ball 214. PCB 220 is similar to PCB 120, and includes a BGA pad 222, ground planes 230 and 232 in a first metal layer of the PCB, a ground plane 236 in a second metal layer of the PCB, and a signal channel 240. Signal interface 212 is electrically connected to BGA ball 214, and BGA device 210 is affixed to PCB 220 such that BGA ball 214 is electrically connected to BGA pad 222.

BGA pad 222 is shown as being on a top surface of PCB and being connected to channel 240. Channel 240 is similar to channel 140, and will be understood to carry the signal provided by signal interface 212 to another device (not illustrated) with which the signal interface conducts data transactions. Channel 240 is illustrated as being provided within PCB 220. However channel 240 may be implemented as a microstrip trace provided on a surface of the associated PCB, as a strip line trace provided on one or more internal metal layer of the PCB and including one or more metallized circuit vias that conduct the associated signal between the surface layers and the internal metal layers, or as a combination of microstrip traces and strip line traces, as needed or desired.

Ground planes 230, 232, and 236 represent internal metal layers of PCB 220 that are electrically connected to a system ground of information handling system 200, and may typically be understood to represent first and second grounded metal layers that are closest to the surface of the PCB proximate to BGA pad 222. Ground planes 230, 232, and 236 may be provided as circuit ground layers for the components and circuits of information handling system 200, or as a reference plane for shielding high speed circuit traces such as channel 240, as needed or desired. Ground planes 230 and 232 are on the first metal layer, but are fabricated with a void 234 between the ground planes. In particular, ground planes 230 and 232 typically represent a common ground plane, with a cut-out of the metallization to form void 234. In any case, void 234 is provided so that the stray capacitance between BGA pad 222 and the first metal layer is reduced. In particular, void 234 acts to move the primary stray capacitance with BGA pad 222 to the second metal layer and ground plane 236, thereby reducing the capacitance through the void (Cvoid) to a level below the stray capacitance (Cstray₁) shown above with reference to FIG. 1B. The dimensions provided herein are not meant to represent actual dimensions for an information handling system.

FIG. 2B illustrates a circuit model of information handling system 200, where signal interface 212 is connected to channel 240, and to the ground plane of the information handling system through an effective capacitor 252. Capacitor 252 represents a stray capacitance between the metallization of BGA pad 222 and the metallization of ground plane 236. The capacitance of capacitor 252 (Cvoid) will be understood to be typically in a range of 50-100 pico-Farads (pF). At the current time the PCB topology of PCB 220 is common, and will be understood to provide adequate signal performance for common signal frequencies for current high-speed data interfaces. However, such a topology may yet result in an impedance reduction of 10-20 Ω in the frequency ranges of soon upcoming high-speed data interfaces.

FIG. 3A illustrates an information handling system 300 in accordance with an embodiment of the current disclosure. Information handling system 300 is similar to information handling systems 100 and 200, and includes a BGA device 310 that is affixed to a PCB 320. BGA device 310 is configured to provide dual input/output channels for the high-speed data communication interface of interest, and thus includes a first signal interface 312 that is similar to signal interfaces 112 and 212, and a second signal interface 316 that is configured to handle a common data signal. Thus signal interface 312 and signal interface 316 may represent a common single-ended signal interface, a common first signal interface of a differential pair signal interface, or another type of signal interface, as needed or desired. In order to provide adequate signal quality on a high-speed data interface, BGA device manufacturers are starting to provide two inputs/outputs for each signal of selected signal interfaces. As such signal interface 312 and signal interface 316 are available as exterior inputs or outputs for the common signal via a BGA ball 314 that is electrically connected to signal interface 312, and a BGA ball 318 that is electrically connected to signal interface 316.

PCB 320 is similar to PCBs 120 and 220, but is configured to accommodate the two input/output configuration of BGA device 310. In this regard, PCB 320 includes a first BGA pad 322 that is electrically connected to BGA ball 312, and a second BGA pad 324 that is electrically connected to BGA ball 318. PCB 320 further includes a shield pad 330 and a ground plane 322 in a metal layer of the PCB, a metalized via 336 between the top layer of the PCB and the metal layer, and a signal channel 340. Via 336 is connected between BGA pad 324 and shield pad 330, as described further below.

BGA device 310 is affixed to PCB 320 such that BGA ball 314 is electrically connected to BGA pad 322, and that BGA ball 318 is electrically connected to BGA pad 324. BGA pad 322 and BGA pad 324 are shown as being on a top surface of PCB and BGA pad 322 is shown as being connected to channel 340. Channel 340 is similar to channels 140 and 240, and will be understood to carry the signal provided by signal interface 312 to another device (not illustrated) with which the signal interface conducts data transactions. Channel 340 is illustrated as being provided within PCB 320. However channel 340 may be implemented as a microstrip trace provided on a surface of the associated PCB, as a strip line trace provided on one or more internal metal layer of the PCB and including one or more metallized circuit vias that conduct the associated signal between the surface layers and the internal metal layers, or as a combination of microstrip traces and strip line traces, as needed or desired. As illustrated, only BGA pad 322 is shown as being connected to channel 340. However PCB 320 may be configured such that BGA pad 324 is not connected to any element of the PCB except as described below (as illustrated here), is connected to BGA pad 322, is connected to channel 140, or is connected to another channel (not illustrated) similar to channel 340 and that runs a similar path through the PCB to the other device, as needed or desired.

Shield pad 330 is connected by via 326 to BGA pad 324 as described above, and extends within the metal layer to span a gap between BGA pad 322 and BGA pad 324, and to underlie BGA pad 324. Shield pad 330 may be understood to extend to directly underneath BGA pad 322, or to extend to be substantially directly underneath BGA pad 322, as needed or desired. That is, shield pad 330 may cover an area directly underneath BGA pad 322 that is slightly larger than the area of the BGA pad, that is substantially equal to the area of the BGA pad, or that is slightly smaller than the area of the BGA pad, as needed or desired. Ground plane 332 represent an internal metal layer of PCB 320 that is electrically connected to a system ground of information handling system 300, and may typically be understood to represent a grounded metal layer that is closest to the surface of the PCB proximate to BGA pad 322. Ground plane 332 may be provided as a circuit ground layers for the components and circuits of information handling system 300, or as a reference plane for shielding high speed circuit traces such as channel 340, as needed or desired.

Shield pad 330 and ground plane 332 are on a common metal layer, but are fabricated with a void 334 between the planes. It will be understood that the configuration provided herein, with shield pad 330 being electrically connected to BGA pad 324, and extending directly underneath BGA pad 322, provides a condition where a signal provided on signal interfaces 312 and 316 are provided in common to BGA pad 322, to BGA pad 324, to via 336, and to shield pad 330. In this way, any voltage swing experienced by BGA pad 322 is likewise experienced on shield pad 330, such that a net voltage difference between BGA pad 322 and shield pad 330 is substantially equal to zero (0) volts (V), and any stray capacitance (Cstray₁) that might be exhibited between BGA pad 322 and shield pad 330 is likewise substantially equal to zero (0) V. Moreover, the only capacitance exhibited on BGA pad 322 is reduced to a stray capacitance (Cstray₂) between the BGA pad and ground layer 332. The dimensions provided herein are not meant to represent actual dimensions for an information handling system.

FIG. 3B illustrates a circuit model of information handling system 300, where signal interface 312 and signal interface 314 are connected to channel 340, and to the ground plane of the information handling system through an effective capacitor 352. Capacitor 352 represents the stray capacitance between the metallization of BGA pad 322 and the metallization of ground plane 332. In particular, shield pad 330 is driven by the same signal as BGA pad 322 such that the buffer of signal interface 316 provides current to charge up the shield pad, rather than expending current from the buffer of signal interface 312, thus increasing the overall response. The capacitance of capacitor 352 (Cstray₂) will be understood to be typically in a range of 1-10 pico-Farads (pF), which will provide adequate signal performance for common signal frequencies for current high-speed data interfaces, and also for upcoming high-speed data interfaces (for example 8-10 GTs or more). In particular, the topology illustrated in FIG. 3A may result in an impedance reduction of only 1-2 Ω.

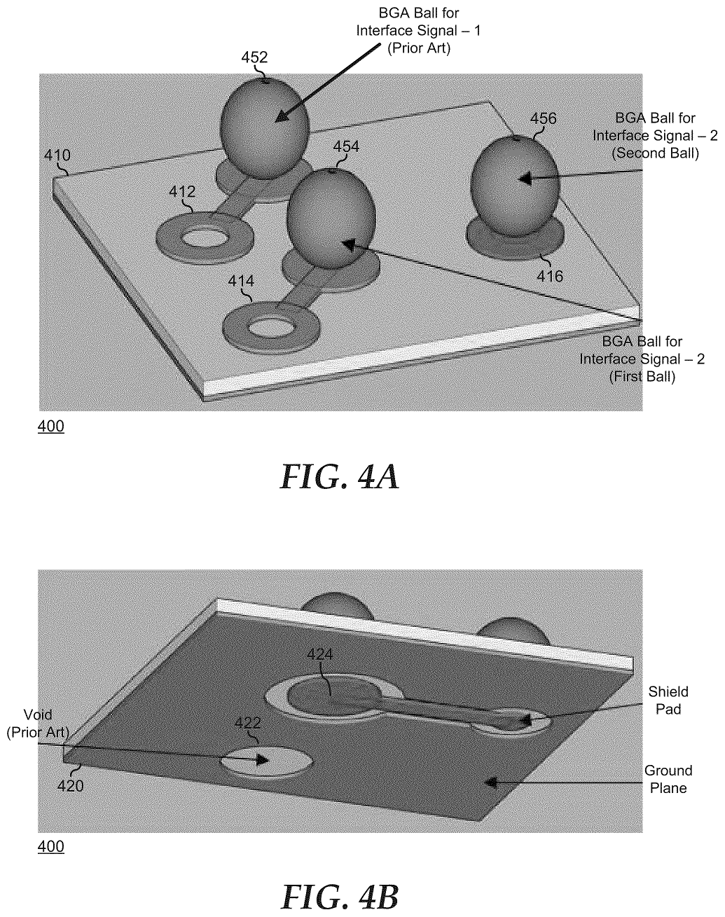

FIG. 4A illustrates a top perspective view of a PCB 400 with features on a top surface 410 illustrated. PCB 400 includes a BGA pad formation 412 for a signal interface according to the prior art as shown in FIG. 2A, above, with a BGA ball 452 associated with a first signal interface of a BGA device (not illustrated). Pad formation 412 is shown as including a BGA pad collocated with a BGA ball 452, and a short trace length to connect the BGA pad to a channel associated with the input/output of the first signal interface. PCB 400 further includes BGA pad formations 414 and 416 for a signal interface according to a current embodiment as shown in FIG. 3A, above. Pad formation 414 includes a BGA pad associated with a first input/output of a second signal interface of the BGA device, and pad 416 includes a BGA pad associated with a second input/output of a second signal interface of the BGA device. Pad formation 414 is shown as including a BGA pad collocated with a BGA ball 454, and a short trace length to connect the BGA pad to a channel associated with the first input/output of the second signal interface, and pad formation 416 is shown as including a BGA pad collocated with a BGA ball 456 associated with the second input/output of the second signal interface.

FIG. 4B illustrates a bottom perspective view of PCB 400, including a metal layer 420 that is connected to a system ground plane. Metal layer 420 includes a void 422 directly underneath the BGA pad of pad formation 412 according to the prior art as shown in FIG. 2A. metal layer 420 further includes a shield pad formation 424 according to a current embodiment as shown in FIG. 3A, above. Shield pad formation 424 includes a plated via interface directly underneath, and electrically connected to pad formation 416, a circuit trace from the via interface, and a shield pad directly underneath the BGA pad of pad formation 414. A signal on the second signal interface from the BGA device will be provided substantially simultaneously on pad formation 414, and the electrically connected structure that includes pad formation 416 and shield pad formation 424, as described above with reference to FIGS. 3A and 3B.

Note that in the above embodiments, the current disclosure is described in the context of BGA devices and BGA pads on a PCB, but this is not necessary to the current embodiments. In particular, it is envisioned by the inventors of the current disclosure that the teachings as described herein may be applicable to other types of devices and their associated contact pads on a PCB. For example, the teachings herein may be applied to any topology where a device is configured to provide dual outputs for each signal of a high-speed data communication interface. In particular, when a PCB is configured to accommodate a surface mount device with contact leads, the contact pads on the PCB may be configured in accordance with the current embodiments, as needed or desired.

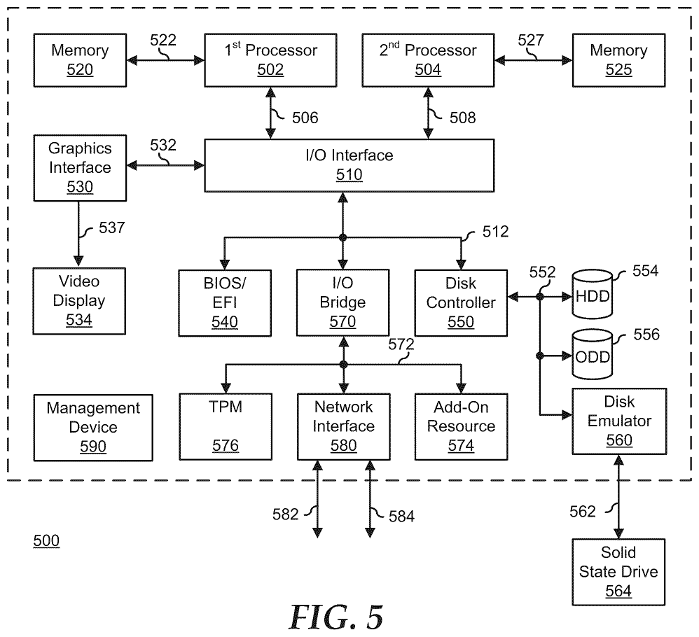

FIG. 5 illustrates a generalized embodiment of an information handling system 500. For purpose of this disclosure an information handling system can include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, information handling system 500 can be a personal computer, a laptop computer, a smart phone, a tablet device or other consumer electronic device, a network server, a network storage device, a switch router or other network communication device, or any other suitable device and may vary in size, shape, performance, functionality, and price. Further, information handling system 500 can include processing resources for executing machine-executable code, such as a central processing unit (CPU), a programmable logic array (PLA), an embedded device such as a System-on-a-Chip (SoC), or other control logic hardware. Information handling system 500 can also include one or more computer-readable medium for storing machine-executable code, such as software or data. Additional components of information handling system 500 can include one or more storage devices that can store machine-executable code, one or more communications ports for communicating with external devices, and various input and output (I/O) devices, such as a keyboard, a mouse, and a video display. Information handling system 500 can also include one or more buses operable to transmit information between the various hardware components.

Information handling system 500 can include devices or modules that embody one or more of the devices or modules described below, and operates to perform one or more of the methods described below. Information handling system 500 includes a processors 502 and 504, an input/output (I/O) interface 510, memories 520 and 525, a graphics interface 530, a basic input and output system/universal extensible firmware interface (BIOS/UEFI) module 540, a disk controller 550, a hard disk drive (HDD) 554, an optical disk drive (ODD) 556, a disk emulator 560 connected to an external solid state drive (SSD) 562, an I/O bridge 570, one or more add-on resources 574, a trusted platform module (TPM) 576, a network interface 580, a management device 590, and a power supply 595. Processors 502 and 504, I/O interface 510, memory 520, graphics interface 530, BIOS/UEFI module 540, disk controller 550, HDD 554, ODD 556, disk emulator 560, SSD 562, I/O bridge 570, add-on resources 574, TPM 576, and network interface 580 operate together to provide a host environment of information handling system 500 that operates to provide the data processing functionality of the information handling system. The host environment operates to execute machine-executable code, including platform BIOS/UEFI code, device firmware, operating system code, applications, programs, and the like, to perform the data processing tasks associated with information handling system 500.

In the host environment, processor 502 is connected to I/O interface 510 via processor interface 506, and processor 504 is connected to the I/O interface via processor interface 508. Memory 520 is connected to processor 502 via a memory interface 522. Memory 525 is connected to processor 504 via a memory interface 527. Graphics interface 530 is connected to I/O interface 510 via a graphics interface 532, and provides a video display output 536 to a video display 534. In a particular embodiment, information handling system 500 includes separate memories that are dedicated to each of processors 502 and 504 via separate memory interfaces. An example of memories 520 and 530 include random access memory (RAM) such as static RAM (SRAM), dynamic RAM (DRAM), non-volatile RAM (NV-RAM), or the like, read only memory (ROM), another type of memory, or a combination thereof.

BIOS/UEFI module 540, disk controller 550, and I/O bridge 570 are connected to I/O interface 510 via an I/O channel 512. An example of I/O channel 512 includes a Peripheral Component Interconnect (PCI) interface, a PCI-Extended (PCI-X) interface, a high-speed PCI-Express (PCIe) interface, another industry standard or proprietary communication interface, or a combination thereof. I/O interface 510 can also include one or more other I/O interfaces, including an Industry Standard Architecture (ISA) interface, a Small Computer Serial Interface (SCSI) interface, an Inter-Integrated Circuit (I²C) interface, a System Packet Interface (SPI), a Universal Serial Bus (USB), another interface, or a combination thereof. BIOS/UEFI module 540 includes BIOS/UEFI code operable to detect resources within information handling system 500, to provide drivers for the resources, initialize the resources, and access the resources. BIOS/UEFI module 540 includes code that operates to detect resources within information handling system 500, to provide drivers for the resources, to initialize the resources, and to access the resources.

Disk controller 550 includes a disk interface 552 that connects the disk controller to HDD 554, to ODD 556, and to disk emulator 560. An example of disk interface 552 includes an Integrated Drive Electronics (IDE) interface, an Advanced Technology Attachment (ATA) such as a parallel ATA (PATA) interface or a serial ATA (SATA) interface, a SCSI interface, a USB interface, a proprietary interface, or a combination thereof. Disk emulator 560 permits SSD 564 to be connected to information handling system 500 via an external interface 562. An example of external interface 562 includes a USB interface, an IEEE 1394 (Firewire) interface, a proprietary interface, or a combination thereof. Alternatively, solid-state drive 564 can be disposed within information handling system 500.

I/O bridge 570 includes a peripheral interface 572 that connects the I/O bridge to add-on resource 574, to TPM 576, and to network interface 580. Peripheral interface 572 can be the same type of interface as I/O channel 512, or can be a different type of interface. As such, I/O bridge 570 extends the capacity of I/O channel 512 when peripheral interface 572 and the I/O channel are of the same type, and the I/O bridge translates information from a format suitable to the I/O channel to a format suitable to the peripheral channel 572 when they are of a different type. Add-on resource 574 can include a data storage system, an additional graphics interface, a network interface card (NIC), a sound/video processing card, another add-on resource, or a combination thereof. Add-on resource 574 can be on a main circuit board, on separate circuit board or add-in card disposed within information handling system 500, a device that is external to the information handling system, or a combination thereof.

Network interface 580 represents a NIC disposed within information handling system 500, on a main circuit board of the information handling system, integrated onto another component such as I/O interface 510, in another suitable location, or a combination thereof. Network interface device 580 includes network channels 582 and 584 that provide interfaces to devices that are external to information handling system 500. In a particular embodiment, network channels 582 and 584 are of a different type than peripheral channel 572 and network interface 580 translates information from a format suitable to the peripheral channel to a format suitable to external devices. An example of network channels 582 and 584 includes InfiniBand channels, Fibre Channel channels, Gigabit Ethernet channels, proprietary channel architectures, or a combination thereof. Network channels 582 and 584 can be connected to external network resources (not illustrated). The network resource can include another information handling system, a data storage system, another network, a grid management system, another suitable resource, or a combination thereof.

Management device 590 represents one or more processing devices, such as a dedicated baseboard management controller (BMC) System-on-a-Chip (SoC) device, one or more associated memory devices, one or more network interface devices, a complex programmable logic device (CPLD), and the like, that operate together to provide the management environment for information handling system 500. In particular, management device 590 is connected to various components of the host environment via various internal communication interfaces, such as a Low Pin Count (LPC) interface, an Inter-Integrated-Circuit (I2C) interface, a PCIe interface, or the like, to provide an out-of-band (OOB) mechanism to retrieve information related to the operation of the host environment, to provide BIOS/UEFI or system firmware updates, to manage non-processing components of information handling system 500, such as system cooling fans and power supplies. Management device 590 can include a network connection to an external management system, and the management device can communicate with the management system to report status information for information handling system 500, to receive BIOS/UEFI or system firmware updates, or to perform other task for managing and controlling the operation of information handling system 500. Management device 590 can operate off of a separate power plane from the components of the host environment so that the management device receives power to manage information handling system 500 when the information handling system is otherwise shut down. An example of management device 590 include a commercially available BMC product or other device that operates in accordance with an Intelligent Platform Management Initiative (IPMI) specification, a Web Services Management (WSMan) interface, a Redfish Application Programming Interface (API), another Distributed Management Task Force (DMTF), or other management standard, and can include an Integrated Dell Remote Access Controller (iDRAC), an Embedded Controller (EC), or the like. Management device 590 may further include associated memory devices, logic devices, security devices, or the like, as needed or desired.

Although only a few exemplary embodiments have been described in detail herein, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents, but also equivalent structures.

The above-disclosed subject matter is to be considered illustrative, and not restrictive, and the appended claims are intended to cover any and all such modifications, enhancements, and other embodiments that fall within the scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A printed circuit board (PCB), comprising:
a first ball grid array (BGA) pad on a first surface of the PCB, the first BGA pad being collocated with a first BGA ball of a BGA device, the first BGA ball being associated with a first signal of the BGA device;
a second BGA pad on the first surface, the second BGA pad being collocated with a second BGA ball of the BGA device, the second BGA ball being associated with a second signal of the BGA device, wherein the first signal and the second signal are a common signal;
a metal layer within the PCB, the metal layer including a shield pad, wherein the shield pad includes a first portion directly below the first BGA pad and a second portion directly below the second BGA pad, and wherein the first portion is coupled to the second portion; and
a plated via that couples the second BGA pad to the shield pad.

2. The PCB of claim 1, wherein the second portion is smaller than the first BGA pad.

3. The PCB of claim 1, wherein the second portion is equal to a size of the first BGA pad.

4. The PCB of claim 1, wherein the second portion is larger than the first BGA pad.

5. The PCB of claim 1, further comprising:
a channel coupled to the first BGA pad.

6. The PCB of claim 5, wherein the channel is configured to provide a signal path for the common signal to another location within the PCB, the other location being associated with another device.

7. The PCB of claim 5, wherein the channel is instantiated within the first surface of the PCB and at least one of a plurality of metal layers within the PCB.

8. The PCB of claim 1, wherein the metal layer includes a ground plane.

9. The PCB of claim 1, wherein the metal layer is one of a plurality of metal layers of the PCB.

10. The PCB of claim 1, wherein the metal layer is a ground layer of the PCB that is closest to the first surface of the PCB.

11. A method, comprising:
providing, on a first surface of a printed circuit board (PCB), a first ball grid array (BGA) pad, the first BGA pad being collocated with a first BGA ball of a BGA device, the first BGA ball being associated with a first signal of the BGA device;
providing, on the first surface of the PCB, a second BGA pad on the first surface, the second BGA pad being collocated with a second BGA ball of the BGA device, the second BGA ball being associated with a second signal of the BGA device, wherein the first signal and the second signal are a common signal;
providing, within the PCB, a metal layer including a shield pad, wherein the shield pad includes a first portion directly below the first BGA pad and a second portion directly below the second BGA pad, and wherein the first portion is coupled to the second portion; and
providing a plated via that couples the second BGA pad to the shield pad.

12. The method of claim 11, wherein the second portion is smaller than the first BGA pad.

13. The method of claim 11, wherein the second portion is equal to a size of the first BGA pad.

14. The method of claim 11, wherein the second portion is larger than the first BGA pad.

15. The method of claim 11, further comprising coupling a channel to the first BGA pad.

16. The method of claim 15, wherein the channel is configured to provide a signal path for the common signal to another location within the PCB, the other location being associated with another device.

17. The method of claim 15, wherein the channel is instantiated within the first surface of the PCB and at least one of a plurality of metal layers within the PCB.

18. The method of claim 11, wherein the metal layer includes a ground plane.

19. The method of claim 11, wherein the metal layer is one of a plurality of metal layers of the PCB.

20. A printed circuit board (PCB), comprising:
a contact pad on a first surface of the PCB, the first contact pad being collocated with a first contact lead of a device, the first contact lead being associated with a first signal of the device;
a second contact pad on the first surface, the second contact pad being collocated with a second contact lead of the device, the second contact lead being associated with a second signal of the device, wherein the first signal and the second signal are a common signal;
a metal layer within the PCB, the metal layer including a shield pad, wherein the shield pad includes a first portion directly below the first contact pad and a second portion directly below the second contact pad, and wherein the first portion is coupled to the second portion; and
a plated via that couples the second contact pad to the shield pad.
